(19) United States
(12) Patent Application Publication
(10) Pub. No.: US 2012/0237878 A1
(43) Pub. Date: Sep. 20, 2012

(54) METHOD AND SYSTEM FOR PROVIDING A SIDE SHIELD FOR A PERPENDICULAR MAGNETIC RECORDING POLE

(75) Inventors: XIANZHONG ZENG, FREMONT, CA (US); DUJIANG WAN, FREMONT, CA (US); HONGPING YUAN, FREMONT, CA (US); LING WANG, HERCULES, CA (US); MIAO WANG, FREMONT, CA (US); HAI SUN, MILPITAS, CA (US)

(73) Assignee: WESTERN DIGITAL (FREMONT), LLC, Fremont, CA (US)

(21) Appl. No.: 13/051,884

(22) Filed: Mar. 18, 2011

(51) Int. Cl. G03F 7/20

(52) U.S. Cl. 430/319

(57) ABSTRACT

A method for fabricating a magnetic transducer having a nonmagnetic intermediate layer is described. A pole is provided on the intermediate layer. The pole has sides, a bottom, a top wider than the bottom and a leading bevel proximate to an ABS location. A side gap is provided adjacent to at least the sides of the pole. A bottom antireflective coating (BARC) layer is provided on the intermediate layer. The BARC layer is removable using a wet etchant and is adjacent to at least a portion of the side gap. A mask layer is provided on the BARC layer. A pattern is photolithographically transferred into the mask layer, forming a shield mask. Part of the BARC layer is exposed to the wet etchant such that the sides of the pole and the side gap are free of the BARC layer. At least a magnetic side shield is provided.

### BACKGROUND

FIG. 1 is a flow chart depicting a conventional method 10 for fabricating a conventional perpendicular magnetic recording (PMR) transducer. For simplicity, some steps are omitted. The conventional method 10 is used for providing a PMR pole in an aluminum oxide layer. A trench is formed in the aluminum oxide layer, via step 12. The top of the trench is wider than the trench bottom. As a result, the PMR pole formed therein will have its top surface wider than its bottom. Consequently, the sidewalls of the PMR pole will have a reverse angle. The bottom of the trench may also be sloped to provide a leading edge bevel. A Ru gap layer is deposited, via step 14. The Ru gap layer is used in forming a side gap. Step 14 typically includes depositing the Ru gap layer using chemical vapor deposition (CVD). The conventional PMR pole materials are plated, via step 16. Step 16 may include plating ferromagnetic pole materials as well as seed and/or other layer(s). A chemical mechanical planarization (CMP) may then be performed, via step 18, to remove excess pole material(s). A top, or trailing edge, bevel may then be formed, via step 20. The write gap is deposited, via steps 22. A conventional photoresist shield mask is formed using conventional photolithography, via step 24. A wraparound shield is then deposited, via step 26.

FIGS. 2 and 3 depict side and air-bearing surface (ABS) views, respectively, of a portion of a conventional PMR transducer 50 formed using the conventional method 10. The conventional transducer 50 is shown during formation in FIG. 2. The conventional transducer 50 includes an intermediate layer 52. The intermediate layer 52 is the layer on which the pole is formed. Also shown is a bevel 53 used informing the leading edge bevel of the pole. Also shown is photoresist shield mask 82. The direction of light used in patterning the mask 82 is shown by straight arrows in FIG. 2. FIG. 3 depicts the conventional PMR transducer after fabrication is completed The Ru gap layer 54 which is deposited in the trench (not shown) is also depicted. The conventional pole 60, write gap 70 and top shield 80 are also shown. Thus, using the conventional method 10, the pole 60 may be formed.

Although the conventional method 10 may provide the conventional PMR transducer 50, there may be drawbacks. As shown in FIG. 2, the photoresist mask 82 may exhibit notches 84. The resist notching 84 is near the base of the photoresist mask 82. As a result, the shield plated in step 26 may have an undesirable profile. Further, the notching 84 may not be controllable, particularly in high volume processes. As a result, yield and/or performance for the conventional PMR transducer 50 may be adversely affected. Further, as can be seen in FIG. 3, resist residue 82′ and 82″ from the photoresist mask 82 may be present. The reverse angle of the conventional pole 60 (e.g. top being wider than the bottom) and associated structures may result in an inability to remove portions of the resist mask 82 from the shadowed regions near the bottom of the conventional pole 60. As a result, the typically organic resist residue 82′ and 82″ may be present in the final device. This resist residue 82′ and 82″ occupies regions that are desired to be part of the wraparound shield 80. Consequently, performance and/or yield may again degrade. Accordingly, what is needed is an improved method for fabricating a PMR transducer.

### SUMMARY

A method for fabricating a magnetic transducer having a nonmagnetic intermediate layer is described. A pole is provided on the intermediate layer. The pole has sides, a bottom, a top wider than the bottom and a top bevel proximate to an ABS location. A side gap is provided adjacent to at least the sides of the pole. A bottom antireflective coating (BARC) layer is provided on the intermediate layer. The BARC layer is removable using a wet etchant and is adjacent to at least a portion of the side gap. A mask layer is provided on the BARC layer. A pattern is photolithographically transferred into the mask layer, forming a shield mask. A portion of the BARC layer is exposed to the wet etchant such that the plurality of sides of the pole and the side gap are free of the BARC layer. At least a side shield is provided. The side shield is magnetic.

### BRIEF DESCRIPTION OF SEVERAL VIEWS OF THE DRAWINGS

FIG. 1 is a flow chart depicting a conventional method for fabricating a PMR transducer.

FIG. 2 is a diagram depicting a side view of a conventional PMR transducer.

FIG. 3 is a diagram depicting an ABS view of a conventional PMR transducer.

FIG. 4 is a flow chart depicting an exemplary embodiment of a method for fabricating a PMR transducer.

FIG. 5 is a diagram depicting a side view of an exemplary embodiment of a PMR transducer during fabrication.

FIG. 6 is a diagram depicting side and ABS views of an exemplary embodiment of a PMR transducer.

FIG. 7 is a flow chart depicting another exemplary embodiment of a method for fabricating a PMR transducer.

FIGS. 8-13 are diagrams depicting an exemplary embodiment of a magnetic recording transducer during fabrication.

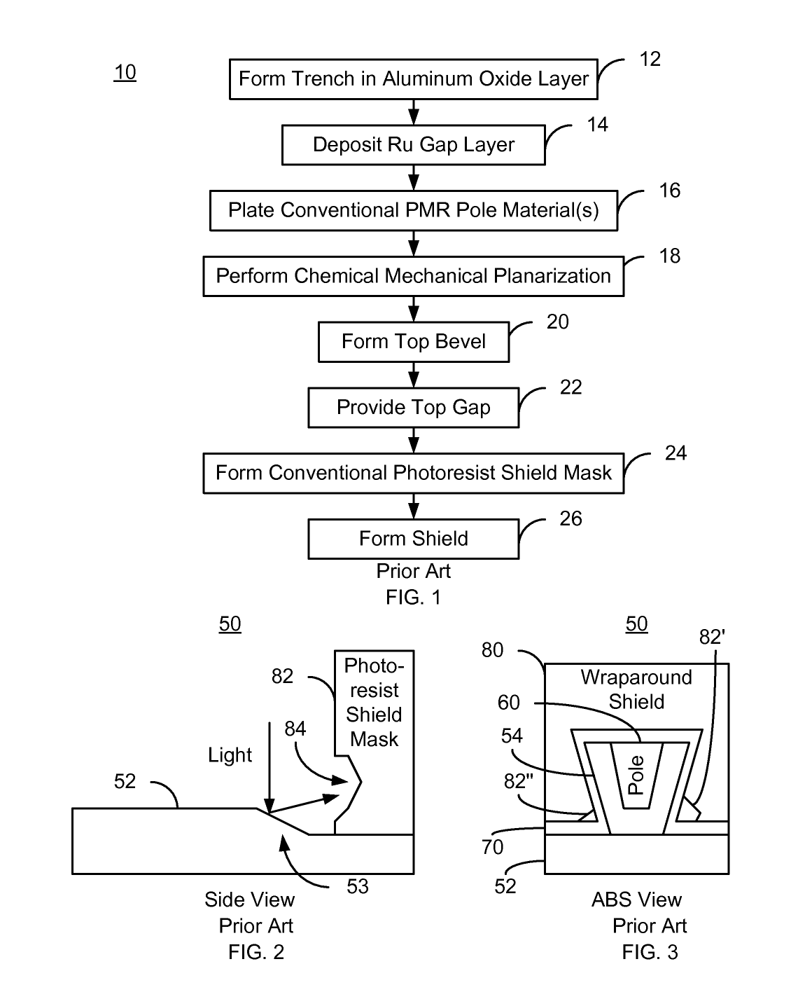

### DETAILED DESCRIPTION OF THE PREFERRED EMBODIMENTS

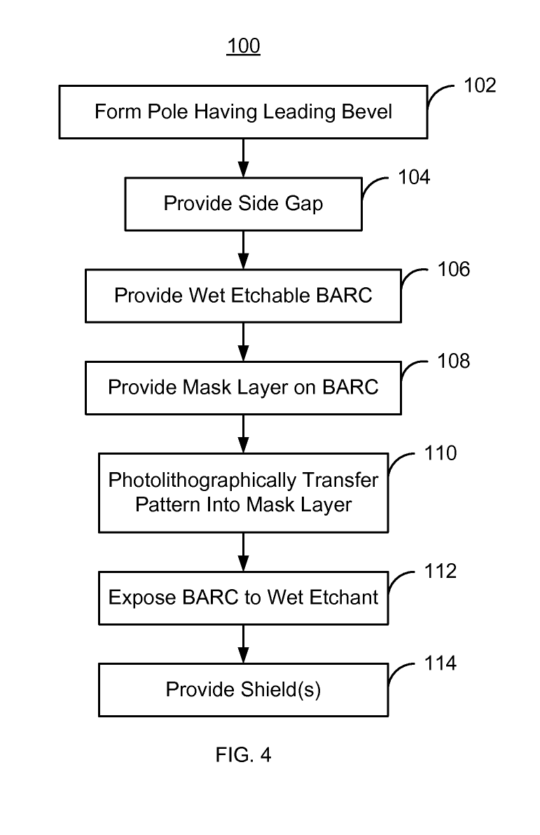

FIG. 4 is a flow chart depicting an exemplary embodiment of a method 100 for fabricating a transducer. The method 100 is described in the context of a PMR transducer, though other transducers might be so fabricated. For simplicity, some steps may be omitted, interleaved, and/or combined. The PMR transducer being fabricated may be part of a merged head that also includes a read head (not shown) and resides on a slider (not shown) in a disk drive. The method 100 also may commence after formation of other portions of the PMR transducer. The method 100 is also described in the context of providing a single PMR pole and its associated structures in a single magnetic recording transducer. However, the method 100 may be used to fabricate multiple transducers at substantially the same time. The method 100 and system are also described in the context of particular layers. However, in some embodiments, such layers may include multiple sub-layers. In one embodiment, the method 100 commences after formation of the intermediate layer(s) on which the PMR pole resides. In some embodiments, a leading edge shield is desired. In such embodiments, the leading edge shield may be part or all of the intermediate layer. The leading edge shield is generally ferromagnetic, magnetically soft, and may include materials such as NiFe.

A pole is provided on the intermediate layer, via step 102. The pole has sides, a bottom, a top wider than the bottom and a leading bevel proximate to an ABS location. The ABS location is the location at which the ABS will be, for example after lapping of the transducer. The leading bevel is at the bottom of the pole and allows the pole tip at the ABS to have a smaller height than a portion of the pole distal from the ABS. In some embodiments, step 102 may include forming a bevel in the intermediate layer or depositing and patterning a sub-layer on the intermediate layer to form the bevel. As used herein, such a sub-layer is considered part of the intermediate layer. The bevel provided in step 102 may have an angle of at least ten and not more than fifty degrees. In some embodiments, the angle of the bevel is thirty degrees, within processing tolerances. The pole provided in step 102 may also be a PMR pole. Because the top of the pole is wider than the bottom, the sidewalls have a reverse angle. In some embodiments, the reverse angle of the pole sidewalls is greater than zero and not more than twenty degrees. In other embodiments, the reverse angle is approximately seven through nine degrees. As part of fabricating the pole, seed layer(s) as well as magnetic layers may be provided. Step 102 may include depositing ferromagnetic and other materials, for example via plating or sputtering. In some embodiments, a planarization such as a CMP may also be performed in providing the pole. In other embodiments, the pole may be fabricated in another manner.

A nonmagnetic side gap adjacent to at least the sides of the pole is provided, via step 104. In some embodiments, a portion of the side gap resides below the pole. Further, in some embodiments, a trench may be formed in the intermediate layer and the side gap deposited in step 104 prior to deposition of the pole materials in step 102.

A bottom antireflective coating (BARC) layer is provided on the intermediate layer, via step 106. The BARC layer is removable using a wet etchant. Thus, the BARC layer is wet etchable using the appropriate wet etchant. The BARC is also adjacent to at least a portion of the side gap. Stated differently, some of the BARC layer is at a location proximate to and, in some embodiments, adjoining the region at which the side gap resides. In some embodiments, the BARC layer is developable. Stated differently, the BARC layer is removable using a developer. An example of such a BARC layer includes ARC DS-K101. The BARC layer is also configured to reduce reflections of light used in step 108, described below. More specifically, the thickness of the BARC layer may be tailored such that light reflecting off of the layer immediately below the BARC layer undergoes destructive interference. Thus, reflections from the underlying layer(s) may be reduced or substantially eliminated.

A mask layer is provided on the BARC layer, via step 108. The mask layer is light sensitive and may be patterned using photolithography. For example, the mask layer might include some type of photoresist. A pattern is then photolithographically transferred into the mask layer, forming a shield mask, via step 110. Step 110 may include exposing a portion of the photoresist layer to light, and then exposing the transducer to a developer that removes the exposed photoresist. In some embodiments, the same developer that is capable of wet etching the BARC layer is also used in photolithographically patterning the mask layer.

A portion of the BARC layer is exposed to the wet etchant that removes the BARC layer, via step 112. As a result, the exposed portions of the BARC layer are removed. More specifically, the sides of the pole and the side gap to which the BARC layer was adjacent are now free of the BARC layer. In embodiments in which the BARC is developable, step 112 may be performed as part of step 110. For example, the developer used in step 110 may be the developer with which the BARC layer can be wet etched. In such an embodiment, removal of the exposed resist and removal of the developable BARC layer may be performed together.

At least a side shield is provided, via step 114. In some embodiments, a full wraparound shield is provided in step 114. In such embodiments, a top gap is desired to be deposited before the wraparound shield is fabricated. In other embodiments, the trailing shield may be fabricated in a separated step. The shield(s) provided in step 114 are magnetic. Thus, step 114 may include plating or otherwise depositing ferromagnetic, magnetically soft, material(s) such as NiFe.

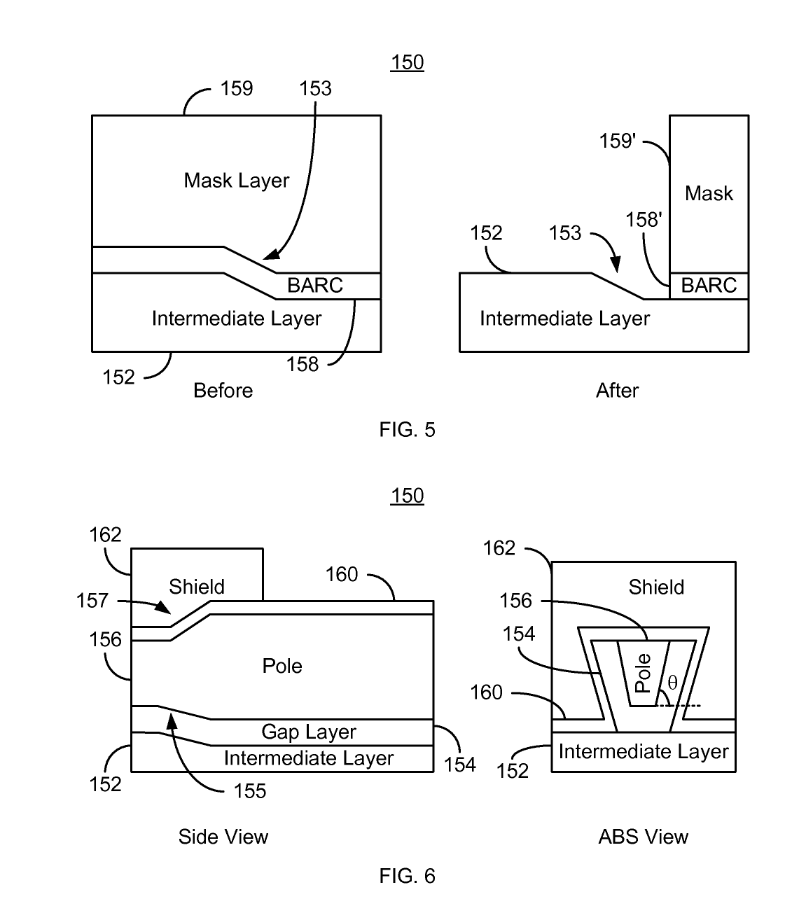

FIGS. 5-6 are diagrams depicting an exemplary embodiment of a portion of a PMR transducer 150 that may be formed using the method 100. For clarity, FIGS. 5-6 are not to scale. FIG. 5 depicts the transducer 150 during formation. The portion of the transducer 150 shown is distal from the pole, where side shields may be formed. Thus, an intermediate layer 152 is shown, but the pole is not depicted in FIG. 5. Also shown is a bevel 153 that has been formed in the intermediate layer 152. The BARC layer 154 and mask layer 159 before step 110 has been performed cover the bevel 153. The BARC layer 158 may be not more than one hundred nanometers thick. In some embodiments, the BARC layer may 158 may be not more than forty nanometers thick, within processing variations. In contrast, the mask layer 159 may be thick. For example, the mask layer 159 may be a deep UV photoresist. In such an embodiment, the mask layer 159 may be on the order of 1.5 microns thick. After steps 110-112 have been performed, the mask 159′ has been formed from mask layer 159. Further, BARC layer 158′ resides only under the mask 159′ because the remaining portion has been exposed to the wet etchant. FIG. 6 depicts the transducer 150 after step 114 is performed. In addition to the intermediate layer 152, gap layer 154 is also shown. Also depicted are pole 156, additional gap layer 160, and shield 162. The pole 156 has a top wider than its bottom and reverse angle, θ. In the embodiment shown, the pole 156 includes not only a leading bevel 155 corresponding to the leading bevel 153, but also an optional trailing bevel 157. In some embodiments, the leading bevel 155 is on the order of two hundred nanometers thick, while the pole 156 is approximately three hundred nanometers thick. Thus, the bevel(s) 155 and 157 may occupy a substantially portion of the height of the pole 156.

Using the method 100, the fabrication of PMR transducers may be improved. As can be seen in FIGS. 5-6, the mask 159′ is substantially free of notching. The presence of the BARC layer 158 may allow for reflections from the bevel 153 to be reduced. Although not shown, a small undercut may be present due to over-removal of the BARC layer 158′. However, the BARC layer 158 is small in comparison to the height of the mask 159. Further, such an undercut may be monitored and controlled during high volume manufacturing. Further, as can be seen in FIG. 6, there is substantially no residue from the mask layer 159 or from the BARC layer 158. This is because the BARC layer 158 is removable using a wet etchant. As a result, the shield 162 has the desired profile. Consequently, manufacturing and performance of the transducer 150 may be improved.

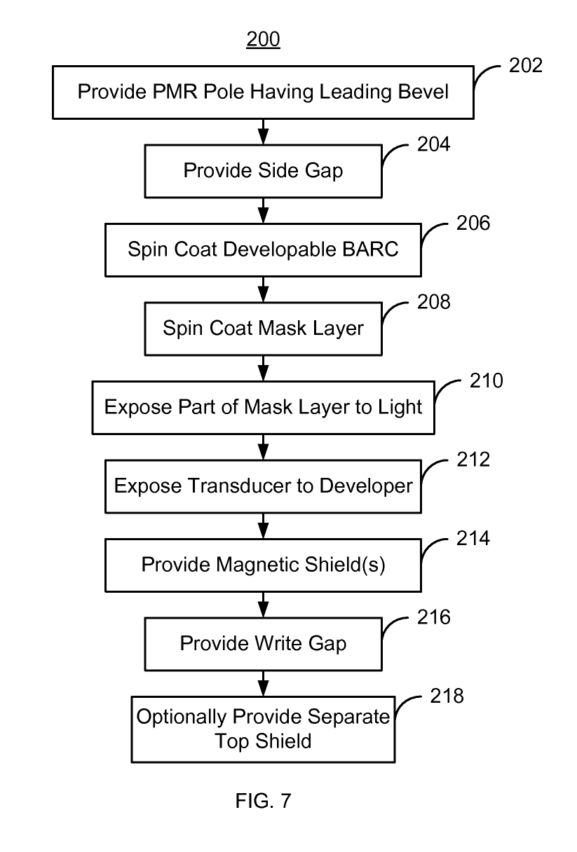

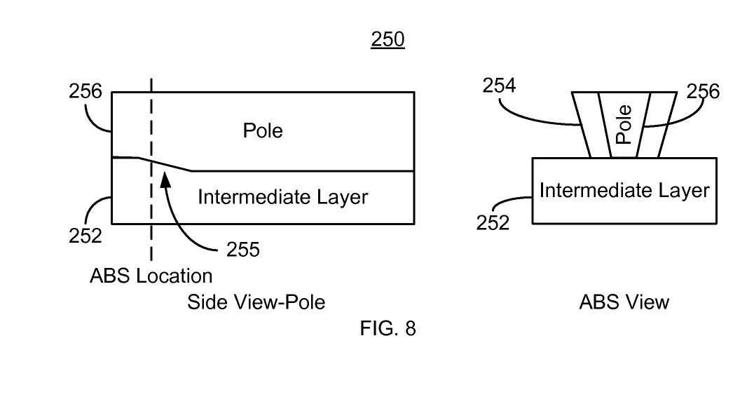

FIG. 7 is a flow chart depicting another exemplary embodiment of a method 200 for fabricating a PMR transducer. For simplicity, some steps may be omitted. FIGS. 8-13 are diagrams depicting side and ABS views of an exemplary embodiment of a portion of a PMR transducer during 250 fabrication. For clarity, FIGS. 8-13 are not to scale. Of the side views, the pole views in FIGS. 8-13 are taken in the middle of the location at which the pole is formed, while the bevel views are taken adjacent to the pole, where the side/wraparound shield is be formed. Further, although FIGS. 8-13 depict the ABS location (location at which the ABS is to be formed) and ABS at a particular point in the pole, other embodiments may have other locations for the ABS. Referring to FIGS. 8-13, the method 200 is described in the context of the PMR transducer 250. However, the method 200 may be used to form another device (not shown). The PMR transducer 250 being fabricated may be part of a merged head that also includes a read head (not shown in FIG. 8-13) and resides on a slider (not shown) in a disk drive. The method 200 also may commence after formation of other portions of the PMR transducer 250. The method 200 is also described in the context of providing a single PMR transducer 250. However, the method 200 may be used to fabricate multiple transducers at substantially the same time. The method 200 and device 250 are also described in the context of particular layers. However, in some embodiments, such layers may include multiple sublayers.

A PMR pole is provided on the intermediate layer, via step 202. Step 202 is analogous to step 102 of the method 100. Step 202 may thus include forming a leading bevel, as well as depositing seed layer(s), magnetic layer(s) and/or other optional layer(s). In some embodiments, step 202 may include forming a bevel in the intermediate layer or depositing and patterning a sub-layer on the intermediate layer to form the bevel. Step 202 may include depositing ferromagnetic and other materials, for example via plating or sputtering. In some embodiments, a planarization such as a CMP may also be performed in providing the pole. In other embodiments, the pole may be fabricated in another manner. A trailing edge bevel may also be provided.

A nonmagnetic side gap is deposited, via step 204. In some embodiments, step 204 may be performed before the PMR pole is provided. In such embodiments, a portion of the side gap is below the PMR pole. FIG. 8 depicts the transducer 250 after step 204 is performed. The intermediate layer 252 on which pole 256 resides is shown. Also depicted is the gap 254. In the embodiment shown, the pole is provided on the intermediate layer 252. However, in other embodiments, the pole may reside on a portion of the gap layer 254. The pole 256 has sides, a bottom, a top wider than the bottom and a leading bevel 255 proximate to an ABS location. Although no trailing bevel is shown, in other embodiments, such a bevel might be included. In some embodiments, the reverse angle of the sidewalls is greater than zero and not more than twenty degrees. In other embodiments, the reverse angle is approximately seven through nine degrees. The bevel 255 may have an angle of at least ten and not more than fifty degrees. In some such embodiments, the angle of the bevel 255 is thirty degrees, within processing tolerances. The transducer 250 may include a leading shield (not shown). In such an embodiment, the intermediate layer 252 may be a leading shield, and a portion of the gap layer 254 or other nonmagnetic layer would reside between the pole 256 and the intermediate layer 252.

A bottom antireflective coating (BARC) layer is spin coated on the intermediate layer, via step 206. The BARC layer is removable using a wet etchant. More specifically, the BARC layer coated in step 206 is a developable BARC, such as ARC DS-K101. The BARC is also adjacent to at least a portion of the side gap. Stated differently, some of the BARC layer is at a location proximate to and, in some embodiments, adjoining the region at which the side gap resides. The BARC layer is also configured to reduce reflections of light used in step 212, described below.

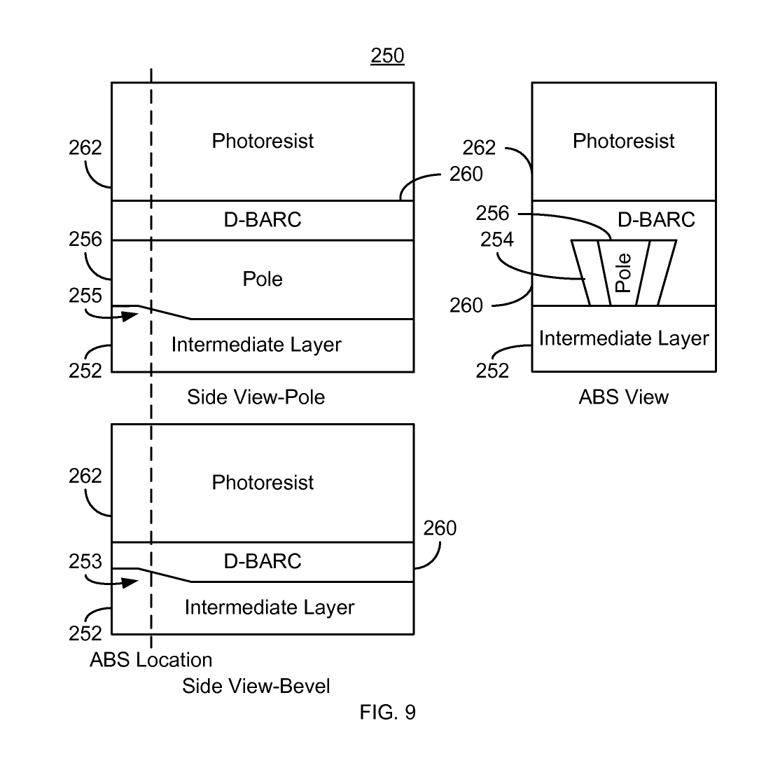

A photoresist mask layer is spin coated on the BARC layer, via step 208. The photoresist mask layer is light sensitive and may be patterned using photolithography. FIG. 9 depicts the transducer after step 208 is performed. In addition, both bevel and pole side views are shown. A developable BARC (D-BARC) layer 260 and photoresist layer 262 are thus shown. Although depicted as having similar thicknesses, in some embodiments, the D-BARC layer 260 may be significantly thinner than the photoresist 262.

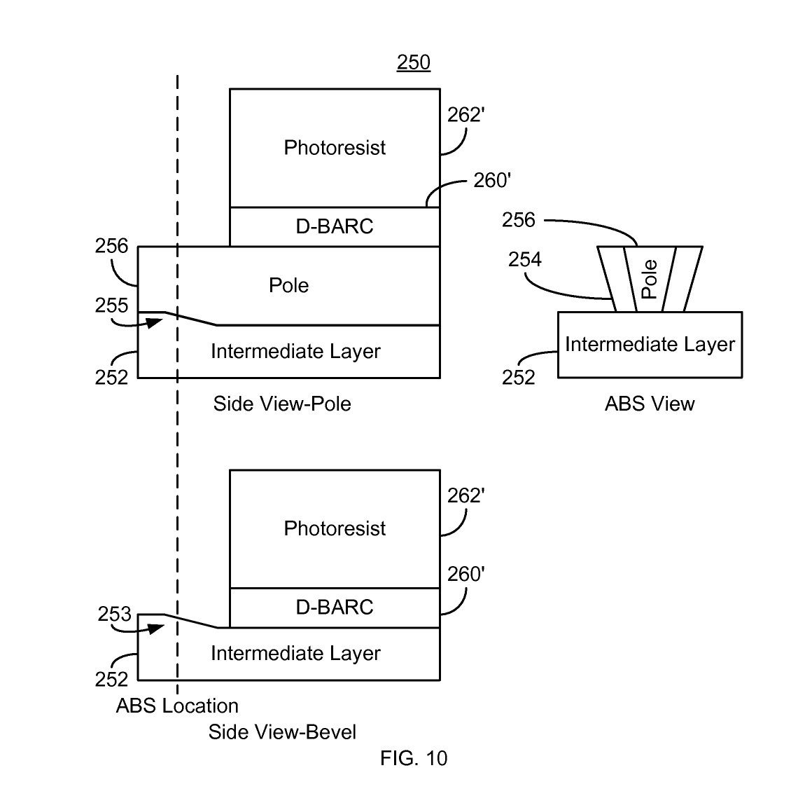

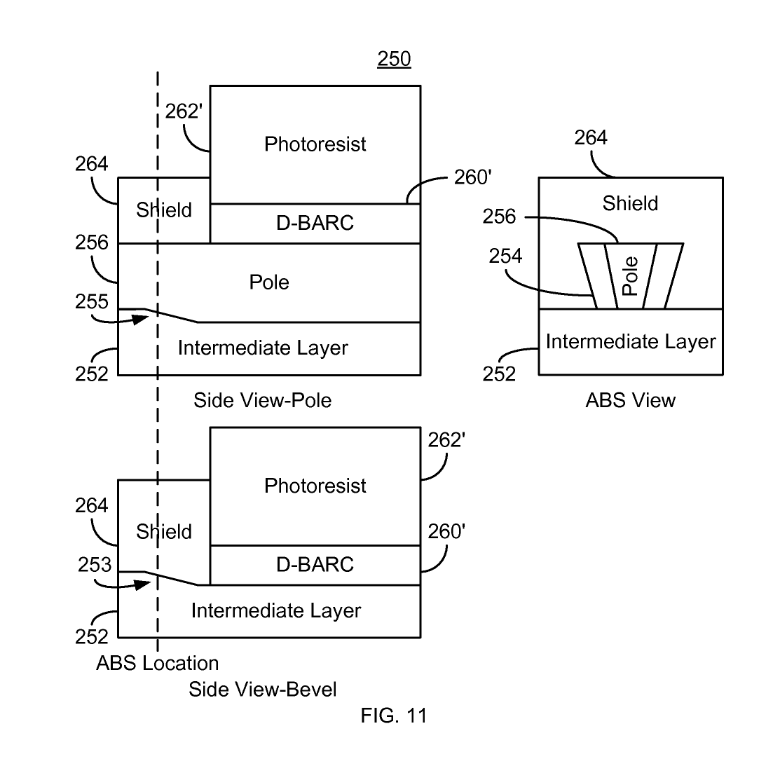

Portions of the mask layer are exposed to the appropriate frequency light to transfer a pattern to the mask layer, via step 210. The transducer 250 is exposed to the developer used in photolithography, via step 212. The developer removes portions of the photoresist layer 262 that have been exposed to light. In addition, because portions of the photoresist layer 262 are removed, the underlying D-BARC layer 260 may also be exposed to the developer. As a result, these portions of the D-BARC layer 260 are also removed. FIG. 10 depicts the transducer 250 after step 214 is performed. Portions of the D-BARC layer 260 and photoresist layer 262 have been removed. Thus, remaining portions of the D-BARC 260′ and photoresist 262′ form a shield mask. As can be seen in FIG. 10, exposure to the developer has removed any portion of the D-BARC layer 260 has been removed from the plurality of sides of the PMR pole 256 and the side gap 254. Further, this removal of the D-BARC 260 has been carried out in connection with photolithographically providing the photoresist mask 262′.

At least a side shield is provided, via step 214. In some embodiments, a full wraparound shield is provided in step 214. In such embodiments, a top gap is desired to be deposited before the wraparound shield is fabricated. In other embodiments, the trailing shield may be fabricated in a separated step. Step 216 may include plating or otherwise depositing ferromagnetic, magnetically soft, material(s) such as NiFe. FIG. 11 depicts the transducer 250 after step 216 is performed. Thus, shield 264 has been deposited. If only a side shield is to be provided, then the portion of the shield 264 above the pole 256 may be removed. If the shield 264 is to be a wraparound shield, then a nonmagnetic gap (not shown) would exist at least between the top of the pole 256 and the shield 264.

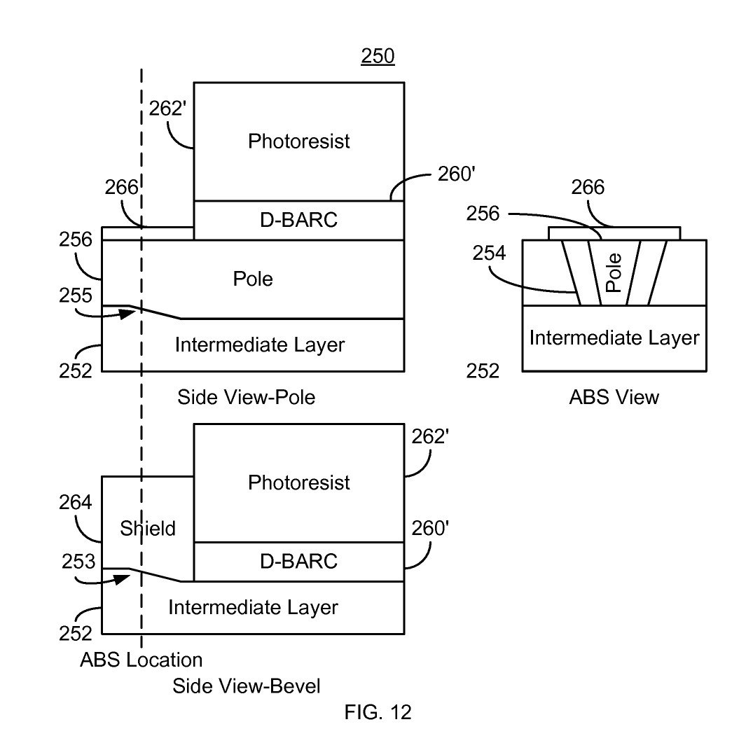

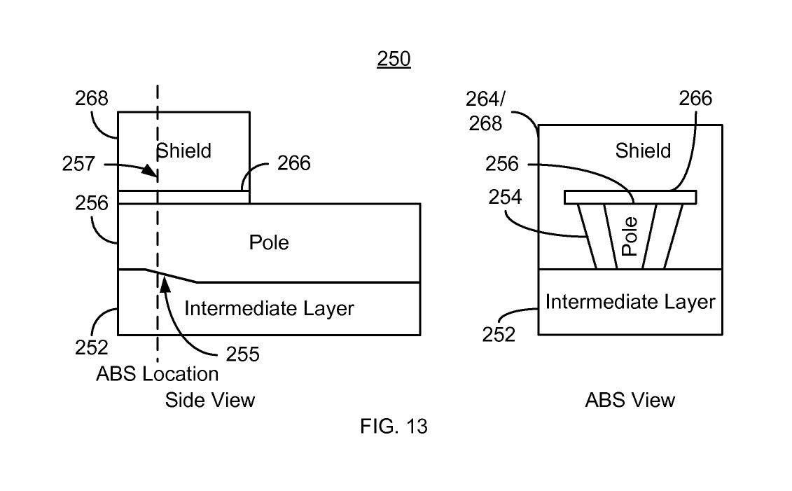

A nonmagnetic gap layer is deposited on at least the PMR pole 256, via step 216. In some embodiments, step 216 may be performed prior to step 206. FIG. 12 depicts the transducer 250 after step 216. Thus, write gap 266 is shown on the pole 256. A magnetic top shield may optionally be provided, via step 220. FIG. 13 depicts the transducer 250 after step 220 is performed. Thus, a trailing shield 268 has been provided. Thus, shields 264 and 268 form a wraparound shield.

Thus, using the method 200, the PMR transducer 250 may be fabricated. The PMR transducer 250 has the desired geometry. In particular, the shield 264/268 has the desired topography. In addition, the transducer may be free of residue from the D-BARC 260 and the photoresist 262. Consequently, manufacturing and performance of the transducer 250 may be improved.

1. A method for fabricating a magnetic transducer having an intermediate layer and an air-bearing surface (ABS), the method comprising:
providing a pole on the intermediate layer, the pole having a plurality of sides, a bottom, a top wider than the bottom and a leading bevel proximate to an ABS location;
providing a side gap adjacent to at least the plurality of sides of the pole;
providing a bottom antireflective coating (BARC) layer on the intermediate layer, the BARC layer being removable using a wet etchant and adjacent to at least a portion of the side gap;
providing a mask layer on the BARC layer;
photolithographically transferring a pattern into the mask layer, forming a shield mask;
exposing a portion of the BARC layer to the wet etchant such that the plurality of sides of the pole and the side gap are free of the BARC layer;
providing at least a side shield, the side shield being magnetic.

2. The method of claim 1 further comprising:
depositing a gap layer on at least the pole and the side gap.

3. The method of claim 2 wherein the step of providing the at least the side shield further includes:
providing a magnetic top shield.

4. The method of claim 1 wherein the BARC layer is developable.

5. The method of claim 4 wherein the BARC layer includes ARC DS-K101.

6. The method of claim 4 wherein the wet etchant is a developer

7. The method of claim 6 wherein the step of photolithographically transferring the pattern further includes:
exposing a portion of the mask layer to light; and
removing the portion of the mask layer using the developer.

8. The method of claim 6 wherein the step of exposing the BARC layer to the wet etchant is performed as part of the step of photolithographically transferring the pattern.

9. The method of claim 2 wherein the BARC layer is not more than one hundred nanometers thick.

11. The method of claim 1 wherein the step of providing the at least the side shield layer further includes:
plating at least one shield layer.

12. The method of claim 1 wherein the pole is a perpendicular magnetic recording write pole.

13. The method of claim 1 wherein the portion of the BARC layer exposed to the wet etchant is uncovered by the shield mask.

14. A method for fabricating a perpendicular magnetic recording (PMR) transducer having an intermediate layer and an air-bearing surface (ABS), the method comprising:
providing a PMR pole on the intermediate layer, the PMR pole having a plurality of sides, a bottom, a top wider than the bottom and a leading bevel proximate to an ABS location;
providing a side gap adjacent to at least the plurality of sides of the pole, the side gap being nonmagnetic;
spin coating a developable bottom antireflective coating (BARC) layer on the intermediate layer, the developable BARC layer being removable using a developer and having a thickness of not more than one hundred nanometers;
spin coating a mask layer on the BARC layer;
exposing a portion of the mask layer to light;
exposing the transducer to the developer, the portion of the mask layer and a portion of the BARC layer being removed by the developer, forming a shield mask and removing any portion of the BARC layer from the plurality of sides of the PMR pole and the side gap layer;
providing a magnetic side shield;
deposit a nonmagnetic gap layer on at least the PMR pole and the side gap; and
providing a magnetic top shield, the nonmagnetic gap layer residing between the PMR pole and the magnetic top shield.
